(19) United States
(12) Patent Application Publication
(10) Pub. No.: US 2005/0023543 A1
(43) Pub. Date: Feb. 3, 2005

(54) Semiconductor light emitting device

(75) Inventor: Kuniaki Konno, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/875,312

(22) Filed: Jun. 25, 2004

(30) Foreign Application Priority Data
Jun. 26, 2003 (JP) 2003-182692

(51) Int. Cl. H01L 33/00

(52) U.S. Cl. 257/94

(57) ABSTRACT

A semiconductor light emitting device comprises a semiconductor substrate, a semiconductor multi-layer, a first electrode and a second electrode. The semiconductor substrate is made of a material which is substantially transparent to a emission wavelength. The semiconductor multi-layer emits a light having the emission wavelength by a current injection. A major surface of the semiconductor multi-layer is bonded to a major surface of the semiconductor substrate and the major surface of the semiconductor substrate has a greater area than the major surface of the semiconductor multi-layer. The first electrode has an ohmic contact part and a light reflecting part. The first electrode is provided on an opposite major surface of the semiconductor multi-layer. A spacing between neighboring portions of the ohmic contact part is greater in an inner part of the first electrode and is smaller in an outer part of the first electrode. The second electrode is provided on an opposite surface of the semiconductor substrate.

### CROSS-REFERENCE TO RELATED APPLICATIONS

This application is based upon and claims the benefit of priority from the prior Japanese Patent Application No. 2003-182692, filed on Jun. 26, 2003; the entire contents of which are incorporated herein by reference.

### BACKGROUND OF THE INVENTION

The present invention relates to a semiconductor light emitting device, especially to a semiconductor light emitting device having a higher light extraction efficiency and a higher light emitting efficiency.

In recent years, there have been proposed and developed many types of the visible light emitting devices in which a semiconductor material of InGaAlP is used. A conventional light emitting device is explained hereinafter. An n-type cladding layer, an active layer and a p-type cladding layer are sequentially grown with InGaAlP based materials on an n-type GaAs substrate, and a double hetero-j unction structure is formed. Subsequently, a p-side contact electrode is formed on the p-type cladding layer, and an n-side contact electrode is formed on the bottom surface of the n-type GaAs substrate.

If the band gaps and lattice constants of an active layer, a p-type cladding layer and an n-type cladding layer are optimized, the desired wavelength become achievable and the higher efficiency is obtained due to effective light confinement. For example, a red light of 644 nm wavelength is emitted when the active layer is made of In_{0.5}(Ga_{0.957}Al_{0.043})_{0.5}P, and the cladding layers of n and p-type are made of In_{0.5} (Ga_{0.3}Al_{0.7})_{0.5}P. Also, a green light of 562 nm wavelength is emitted when the active layer is made of In_{0.5}(Ga_{0.546}Al_{0.454})_{0.5}P, and the cladding layers of n and p-type are made of In_{0.5}Al_{0.5}P. However this conventional device has a serious disadvantage that a part of the emitting light of the shorter wavelength less than 870 nm is absorbed in the GaAs substrate having a band gap corresponding to 870 nm wavelength, and hence the light intensity decreases.

In order to overturn this GaAs absorption problem, a transparent substrate material such as GaP is desirable. Although GaP is non absorptive but transparent to the light of the shorter wavelength than 870 nm, it is difficult to grow high quality InGaAlP based multi-layer epitaxially on the GaP substrate due to the lattice mismatch. To solve above problem, wafer direct bonding technique is used. This technique is disclosed in the Japanese Patent Laid-Open No.2002-111052. However, in the case of the device, the light absorption still occurs in an interface between an n-type current diffusion layer and an n-type contact electrode, and an injected current tends to concentrate in a central portion.

The structure to solve above problems is disclosed in the Japanese Patent Laid-Open No.2002-217450. By this invention, an n-type electrode of the device comprises an ohmic contact metal and a light reflector, disposed alternately. And the spacing between portions of the ohmic contact metal is substantially same in a cross-section. Although this structure has an absorption reduction effect to some extent, the current concentration still exist much due to a same spacing between the portions of the ohmic contact metal. Another invention to solve the current concentration was disclosed in the Japanese Patent Laid-Open No.11-163396. By this invention, on both surfaces of a device a few electrodes are disposed, respectively. Although this structure can separate the current region, it requires a larger device size and a lot of bonding wires.

### SUMMARY OF THE INVENTION

According to an aspect of the invention, there is provided a semiconductor light emitting device comprising:
a semiconductor substrate of which material is substantially transparent to a emission wavelength;
a semiconductor multi-layer which emits a light having the emission wavelength by a current injection, a major surface of the semiconductor multi-layer being bonded to a major surface of the semiconductor substrate and the major surface of the semiconductor substrate having a greater area than the major surface of the semiconductor multi-layer;
a first electrode having an ohmic contact part and a light reflecting part, the first electrode being provided on an opposite major surface of the semiconductor multi-layer, a spacing between neighboring portions of the ohmic contact part in an inner part of the first electrode being greater than a spacing between neighboring portions of the ohmic contact part in an outer part of the first electrode; and
a second electrode provided on an opposite surface of the semiconductor substrate.

According to another aspect of the invention, there is provided a semiconductor light emitting device comprising:
a semiconductor substrate of which material is substantially transparent to a emission wavelength;
a semiconductor multi-layer which emits a light having the emission wavelength by a current injection, a major surface of the semiconductor multi-layer being bonded to a major surface of the semiconductor substrate and the major surface of the semiconductor substrate having a greater area than the major surface of the semiconductor multi-layer;
a first electrode having an ohmic contact part and a light reflecting part, the first electrode being provided on an opposite major surface of the semiconductor multi-layer, a width of the ohmic contact part being wider in an outer part of the first electrode and being narrower in an inner part of the first electrode; and
a second electrode provided on an opposite surface of the semiconductor substrate.

According to another aspect of the invention, there is provided a semiconductor light emitting device comprising:
a GaP semiconductor substrate having a first major surface, a second major surface wider than the first major surface and a slanting side surface provided between the first and second major surfaces;
a semiconductor multi-layer including an InGaAlP active layer and a GaAs ohmic contact layer, a major surface of the semiconductor multi-layer being bonded to the second major surface of the GaP substrate and the major surface of the semiconductor multi-layer being smaller than the second major surface of the GaP substrate;
a first electrode having an ohmic contact part and a light reflecting part, the first electrode being provided on the GaAs contact layer; and
a second electrode provided on the first major surface of the GaP substrate.

### BRIEF DESCRIPTION OF THE DRAWINGS

The present invention will be understood more fully from the detailed description given herebelow and from the accompanying drawings of the embodiments of the invention. However, the drawings are not intended to imply limitation of the invention to a specific embodiment, but are for explanation and understanding only.

In the drawings:

FIG. 1A is a cross-sectional view of the semiconductor light emitting device according to a first embodiment of the invention;

FIG. 1B is a bottom plan view taken along a line A-A of FIG. 1A;

FIG. 1C is a bottom plan view taken along a line A-A of FIG. 1A;

FIG. 2A is a cross-sectional view of the semiconductor light emitting device for an experiment;

FIG. 2B is a bottom plan view taken along a line A-A of FIG. 2A;

FIG. 3 shows the relationship between a relative optical output and an area ratio of ohmic contact region to total n-side electrode;

FIG. 4 shows the relationship between a relative luminous flux and a carrier concentration of a p-type GaP substrate;

FIG. 5 shows a bottom plan view of a transformation of the embodiment;

FIG. 6 shows a bottom plan view of another transformation of the embodiment;

FIG. 7A is a cross-sectional view of a semiconductor light emitting device according to a second embodiment of the invention;

FIG. 7B is a bottom plan view taken along a line A-A of FIG. 7A; FIG. 8A is a cross-sectional view of the semiconductor light emitting device according to a third embodiment of the invention;

FIG. 8B is a bottom plan view taken along a line A-A of FIG. 8A; and

FIG. 9 is a cross-sectional view of a conventional light emitting device.

### DETAILED DESCRIPTION

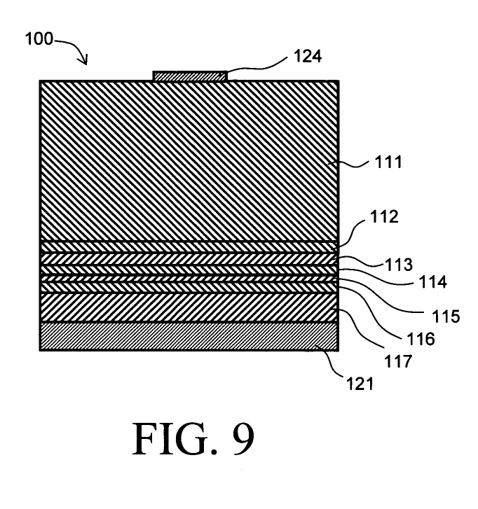

FIG. 9 shows a cross-sectional view of a light emitting device examined by the Inventor in the course of researches toward the present invention. In order to fabricate the device, first, a n-type current diffusion layer 117, an n-type cladding layer 116, ap-type active layer 115, a p-type cladding layer 114 and a p-type bonding layer 113 are grown sequentially on a GaAs substrate (not shown). Second, a p-type GaP layer 112 is grown on a p-type GaP substrate 111. Subsequently, a p-type bonding layer 113 on the GaAs substrate and a p-type GaP layer 112 on the Gap substrate are bonded directly, and then the GaAs substrate is removed.

However there are several problems in above directly bonded device. In the case of device of FIG. 9, the light absorption still occurs in an interface between an n-type current diffusion layer and an n-type contact electrode, and an injected current tends to concentrate in a central portion.

Referring to drawings, some embodiments of the present invention will now be described in detail.

(First Embodiment)

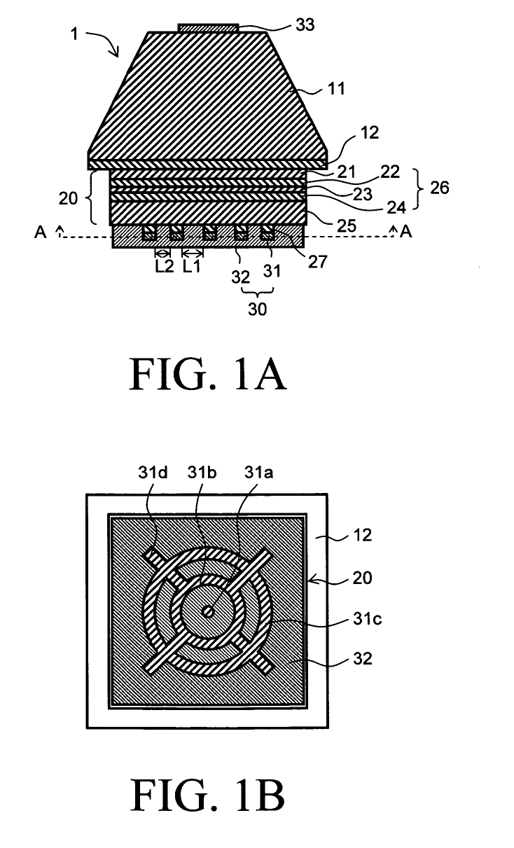

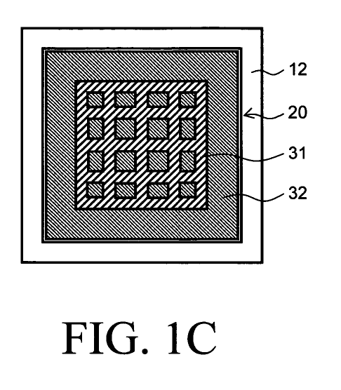

FIG. 1A is a cross-sectional view of the semiconductor light emitting device according to a first embodiment. FIG. 1B is a bottom plan view taken along a line A-A of FIG. 1A. The structure of this light emitting device will be explained in detail hereafter. This light emitting device includes a transparent substrate 11 such as a p-type GaP, a light emitting semiconductor multi-layer directly bonded on the transparent substrate, a n-type GaAs contact layer 27, a first electrode 30 comprising an n-side contact metal 31 and a light reflector 32 on one major surface of the semiconductor multi-layer, and a second electrode 33 of a p-type ohmic contact on one major surface of the p-type GaP substrate. The light emitting diode is a representative example of the light emitting device.

As shown in FIG. 1A, a shape of the GaP substrate 11 is a trapezium of which an upper edge is smaller than a bottom edge. In this embodiment a p-type GaP bonding layer 12 is grown on the GaP substrate 11, but this layer 12 is not necessarily required. The light emitting semiconductor multi-layer 20 has a stack structure so that the light having an inherent wavelength corresponding to an active layer band gap is emitted by the current injection from the pn junction. According to this embodiment, an n-type InAlP cladding layer 24, an p-type InGaAlP active layer 23, a p-type InAlP cladding layer 22, and a p-type InGaP bonding layer 21 are grown on an n-type current diffusion layer 25. This active layer may be a single layer or an MQW structure. A double hetero structure 26 comprises a p-type InAlP cladding layer, a p-type active layer and an n-type InAlP cladding layer. Both cladding layers are disposed on both sides of the active layer and have wider band gaps to confine the carriers for the higher light emitting efficiency. Also a wavelength may be adjusted by the band gap of the active layer. Therefore it is necessary to optimize the band gap of each layer.

The p-type InGaP bonding layer 25 and the p-type GaP bonding layer are bonded directly. In order to obtain the higher extraction efficiency, an area of the p-type GaP bonding layer 12 should be greater than an area of the light emitting semiconductor multi-layer 20, as shown in FIG. 1A. In this case an area of the light emitting semiconductor multi-layer is approximately 70% of that of the p-type GaP bonding layer.

An n-side electrode structure will be now explained hereinafter. A first electrode 30 includes an n-side contact metal 31 and a light reflector 32 which covers the n-side contact metal 31 and an n-type InGaAlP current diffusion layer 25. A n-type GaAs contact layer 27 is interposed between the n-side contact metal and the part of the current diffusion layer 25 to obtain a lower contact resistance, while reducing a light reflection to some extent. On the contrast, the light reflector 32 has a relatively high contact resistance to the current diffusion layer due to non-ohmic contact, but has a higher optical reflection coefficient. For example, AuGe is used for an n-side contact metal and an Au based metal is used for a light reflector.

FIG. 1B shows an example of a concentric n-side contact metal pattern which comprises a central circle 31a, a first concentric ring portion 31b, a second concentric ring portion 31c and four stripes connecting both ring portions.

Also a contact metal may be a grid pattern, as shown in FIG. 1C. In addition, an n-type GaAs contact layer has the same shape as that of an n-side ohmic contact metal and its area is 20% of the light reflector. The ohmic contact metal is disposed so that spacing between the portions of the ohmic contact metal becomes greater in an inner part of the first electrode and smaller in an outer part of the first electrode in a cross-section including a substantially central axis perpendicular to the major surface of the first electrode. In FIG. 1, L1 corresponds to a greater spacing in an inner part and L2 corresponds to a smaller spacing in an outer part.

The reason why above ohmic contact metal configuration is desirable will be explained hereinafter. The Inventor has investigated the relationship between an optical output and an area ratio of an ohmic contact metal to a first electrode during the development of a highly bright light emitting device.

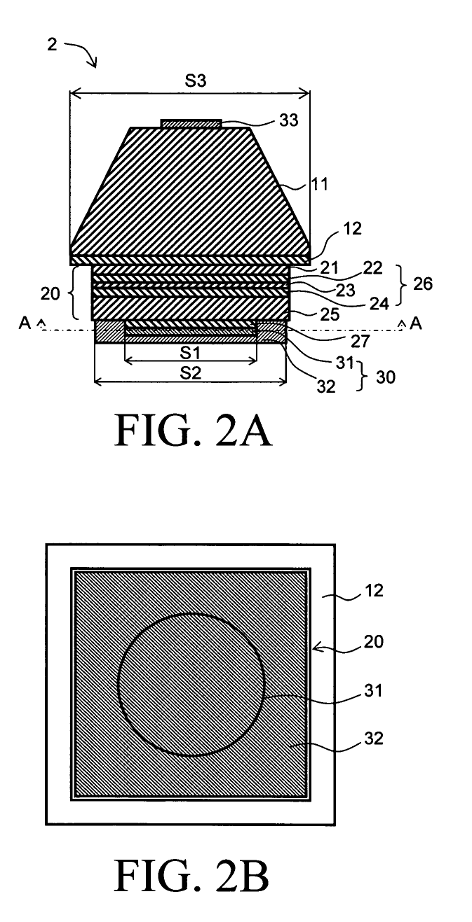

FIG. 2A is a cross-sectional view of the light emitting device for an experiment. Also FIG. 2B is a bottom plan view taken along a line A-A in FIG. 2A. This experimental device has a square-shape light emitting multi-layer 20, a circular n-side ohmic contact metal 31 having an area of S1, and a square-shape light reflector 32 having a area of S2 covering the circular n-side ohmic contact metal. An area of the light emitting multi-layer 20 is 70% of an area S3 of a p-type GaP substrate (on direct bonding surface), and an area of a p-side contact electrode is 50% of that of an upper surface of a p-type GaP substrate 11 in FIG. 2A approximately.

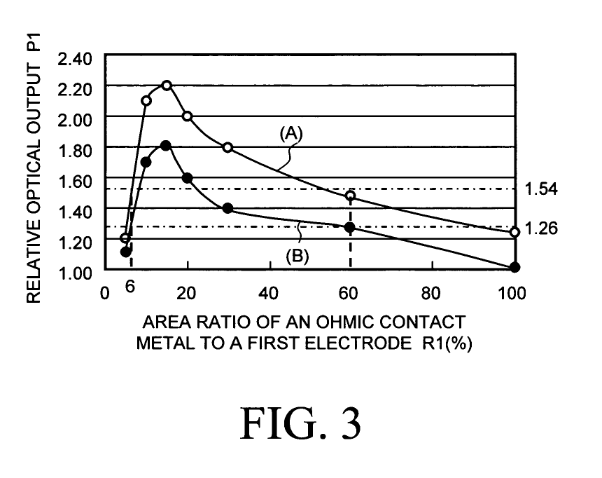

FIG. 3 is a graph showing the experimental result. X-axis represents an area ratio R1 of an n-side ohmic contact metal (S1) to a first electrode (S2), where R1=S1/S2. Y-axis represents a relative optical output P1, wherein an optical output for 100% ohmic contact metal is defined as 1.00 (relative value). The curve (B) in FIG. 3 shows that an optical output P1 increases according to the decrease of the area ratio R1 apart from 100%, reaches the maximum at R1=15%, and decreases according to decrease of R1 rapidly.

The reasons are considered to be as follows: The rapid fall of an optical output at a lower ohmic contact area ratio R1 is induced by poor heat radiation capability due to a higher diode forward voltage that is reinforced with the decrease of an area ratio R1. Therefore, the output maximum exists at a certain area ratio where the heat radiation is consistent with the optical reflection. If 70% of the maximum output is a practically allowable lower limit, the area ratio R1 may be within a range 6 to 60%. In addition, because the spacing is greater in an inner part and smaller in an outer part, the current concentration effect is improved and the active region expands, compared to the conventional device. And a curve (A) in FIG. 3 shows the same relationship when an area of a p-type GaP bonding layer is half of the device described in above example of (B). A curve (A) shows that a GaP device of half area has the same optical output-area ratio tendency and relative output becomes 20-30% higher. This reason is considered below. The smaller light emitting area causes the higher injection current density.

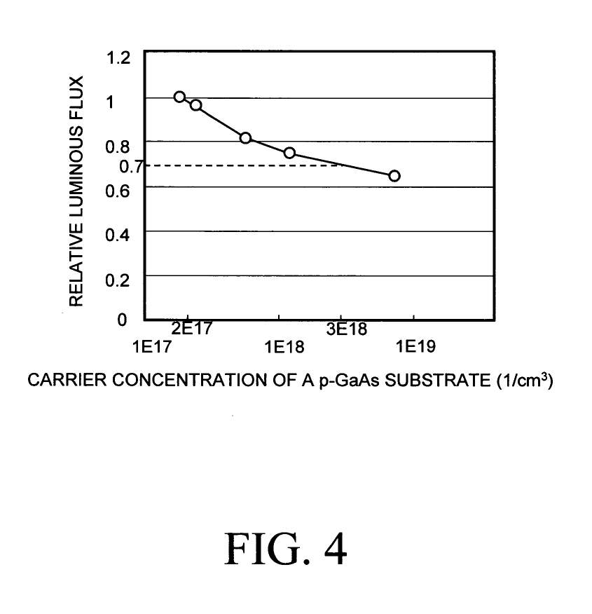

A relationship between a carrier concentration of a p-type GaP substrate and the luminous flux will be now explained hereinafter. In this experimental device an area ratio R1 is approximately 20% and an area of a p-type GaP bonding layer is half of S3. X-axis represents a carrier concentration of a p-type GaP and Y-axis represents the relative luminous flux, in FIG. 4. A lower limit of the carrier concentration is determined so that the diode forward characteristic is not degraded, and is 2×10¹⁷/cm³ approximately.

The Y-axis represents the relative luminous flux, assuming that the luminous flux is 1.00 at a p-type carrier concentration of 2×10¹⁷/cm³. The relative luminous flux decreases monotonously according to the increase of the concentration of the p-type GaP substrate. This reason is considered to be as follows:

During transmitting through a GaP substrate, an emitting light is scattered and absorbed by impurities and these scattering and absorption increase according to the carrier concentration. Consequently, the optical extraction efficiency becomes lower. Therefore the desirable carrier concentration should be within a range of 2×10¹⁷ to 3×10¹⁸/cm³, preferably 6×10¹⁷/cm³, by Zn doping. The upper limit of the concentration is determined newly because the luminous flux becomes less than 0.7 of relative intensity and this is an allowable flux limit. Conventionally the higher concentration more than 3×10¹⁸/cm³ was used practically and caused a lot of optical loss.

In the light emitting device shown in FIG. 1, the bottom surface of the light reflector 32 is bonded on an electrode in a package by metal eutectic solders or the like, and a p-side contact electrode 33 is connected with another electrode in the package by the bonding wires.

In summary, a first embodiment of the invention provides the light emitting device having a smaller area of a light emitting semiconductor multi-layer, a greater area of a transparent semiconductor substrate bonded to the multi-layer, and an electrode which includes an ohmic contact metal and a light reflector with an appropriate area ratio and a configuration. According to the first embodiment, it becomes possible to obtain a higher current density, a wider effective active region, a higher reflection coefficient and a higher extraction efficiency due to minimizing an absorption. Consequently the optical output may be doubled compared to a conventional semiconductor light emitting device.

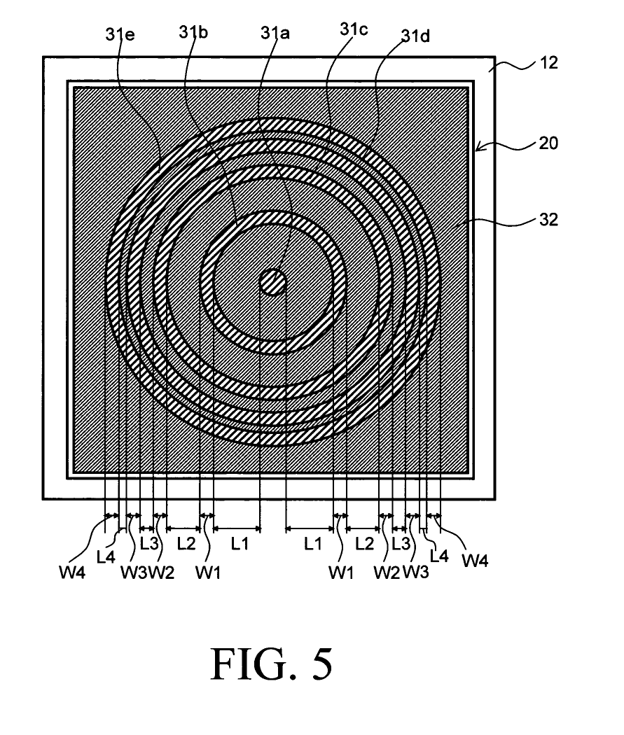

FIG. 5 shows a bottom plan view of a transformation of the embodiment. That is, FIG. 5 corresponds to a bottom view taken from a line A-A in FIGS. 1A. As shown in the figure, the n-side contact metal pattern can be formed to have a central circle 31a, and first through fourth concentric ring portions 31b-31e. The width (W1-W4) of each ring portions 31b-31e may be the same while the spacing L1-L4 becomes smaller as it comes to the outside. That is, spacing L2 is smaller than the spacing Ll. The spacing L3 is smaller than the spacing L2. The spacing L4 is smaller than the spacing L3.

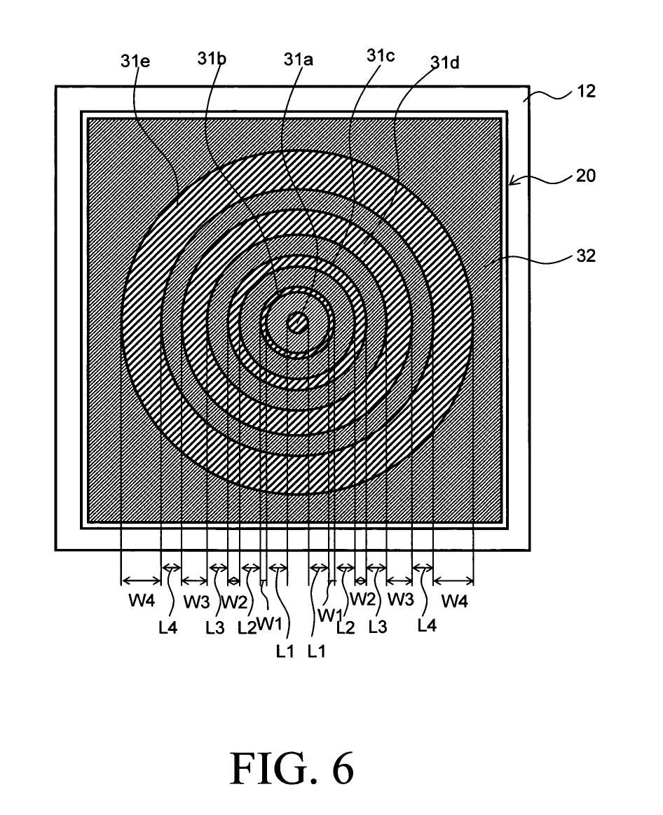

FIG. 6 shows a bottom plan view of another transformation of the embodiment. That is, FIG. 6 corresponds to a bottom view taken from a line A-A in FIGS. 1A. In this transformation, the n-side contact metal pattern is also formed to have a central circle 31a, and first through fourth concentric ring portions 31b-31e. However, in this case, the width of each ring portions 31b-31e is different, and the spacings L1-L4 are the same.

That is, the width W4 is larger than the width W3. The width W3 is larger than the width W2. The width W2 is larger than the width W1.

In these transformations, the optical output can also be improved as explained above.

(Second embodiment)

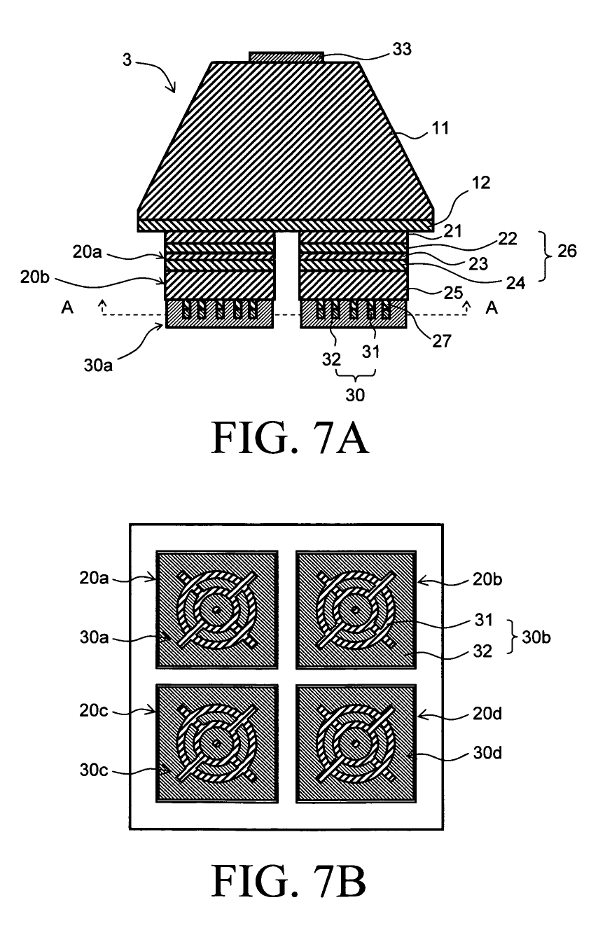

FIG. 7A is a cross-sectional view of the semiconductor light emitting device according to a second embodiment. FIG. 7 B is a bottom plan view taken from a line A-A in FIG. 7A. Since the same portions have the same number as those of the first embodiment, the explanation is omitted and the different portions are only explained. In this embodiment there provided four semiconductor multi-layers 20a, 20b, 20c, 20d, and four first electrodes 30a, 30b, 30c and 30d. Four semiconductor multi-layers are directly bonded to a p-type GaP bonding layer 12. A total area of the four semiconductor multi-layers is less than an area of the p-type GaP bonding layer. The structures of the semiconductor multi-layer and the first electrode are the same as those of the first embodiment. An advantage of this divided structure is to be able to obtain the higher current density, the greater effective active region and the higher light emitting efficiency due to a distributed light emitting region. Consequently a higher optical output is obtained up to about 2.4 times of the conventional device. In addition, although the first electrodes are divided into four portions, these electrodes are bonded on the common electrode of a package simultaneously and hence assembling process is the same as that of the first embodiment.

(Third Embodiment)

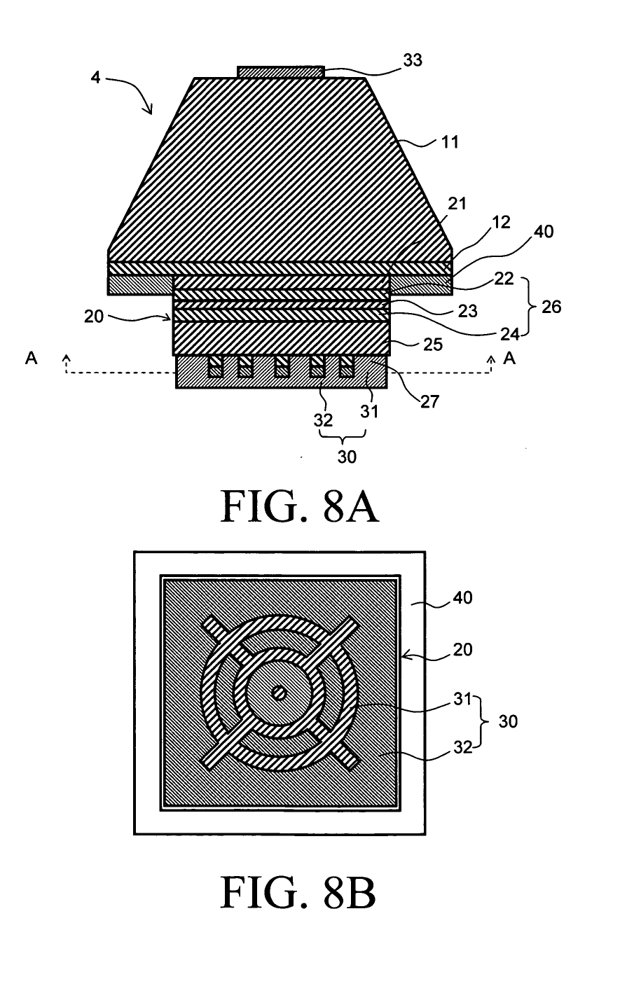

FIG. 8A is a cross-sectional view of the semiconductor light emitting device of a third embodiment. FIG. 8B is a bottom plan view taken along a line A-A of FIG. 8A. In this embodiment an exposed surface on a p-type GaP bonding layer is covered with a light reflector 40. After an emitting light from the active layer 23 enters into the p-type GaP substrate, a portion of the transmitted light propagates to the outside directly and other portion is reflected internally at the surfaces of the trapeziform GaP substrate and finally propagates to the outside. Without the partly covered light reflector 40, a part of the internally reflected light propagates downward through the p-GaP bonding layer 12 in FIG. 8A, so that this light can not be extracted. If a light reflector such as Au film is deposited on that exposed surface, an extraction efficiency can be improved and hence the higher optical output is obtained.

The third embodiment is also applicable to the second embodiment. When a light reflector is disposed on the exposed surface of the p-type GaP bonding layer of FIG. 7B, extraction efficiency and an optical output can be further improved.

Additional advantages and modifications will readily occur to those skilled in the art. More specifically as a material which constitutes the semiconductor light emitting device of this invention, various kinds of material, such as AlGaAs, InP, and GaN can be used instead of InGaAlP. And also an appropriate transparent substrate may be selected.

While the present invention has been disclosed in terms of the embodiment in order to facilitate better understanding thereof, it should be appreciated that the invention can be embodied in various ways without departing from the principle of the invention. Therefore, the invention should be understood to include all possible embodiments and modification to the shown embodiments which can be embodied without departing from the principle of the invention as set forth in the appended claims.

1. A semiconductor light emitting device comprising:
a semiconductor substrate of which material is substantially transparent to a emission wavelength;
a semiconductor multi-layer which emits a light having the emission wavelength by a current injection, a major surface of the semiconductor multi-layer being bonded to a major surface of the semiconductor substrate and the major surface of the semiconductor substrate having a greater area than the major surface of the semiconductor multi-layer;
a first electrode having an ohmic contact part and a light reflecting part, the first electrode being provided on an opposite major surface of the semiconductor multi-layer, a spacing between neighboring portions of the ohmic contact part in an inner part of the first electrode being greater than a spacing between neighboring portions of the ohmic contact part in an outer part of the first electrode; and
a second electrode provided on an opposite surface of the semiconductor substrate.

2. The semiconductor light emitting device according to claim 1, wherein a ratio of an area of the ohmic contact part to an area of the first electrode being within a range of 6 to 60%.

3. The semiconductor light emitting device according to claim 1, wherein the ohmic contact part is not provided in a periphery of the first electrode.

4. The semiconductor light emitting device according to claim 1, wherein the ohmic contact part has a concentric or a grid configuration.

5. The semiconductor light emitting device according to claim 1, wherein the semiconductor multi-layer includes a first cladding layer of a first conductivity type, an active layer provided on the first cladding layer, and a second cladding layer of a second conductivity type provided on the active layer.

6. The semiconductor light emitting device according to claim 1, wherein a structure including the semiconductor multi-layer and the first electrode is divided into a plurality of parts.

7. The semiconductor light emitting device according to claim 1, wherein a light reflector is disposed on an exposed portion of the major surface of the semiconductor substrate.

8. The semiconductor light emitting device according to claim 1, wherein the semiconductor substrate is made of GaP whose carrier concentration is within a range of 2×10¹⁷ to 3×10¹⁸/cm³.

9. The semiconductor light emitting device according to claim 1, wherein the semiconductor substrate has a trapeziform cross-section having a narrower edge toward the second electrode.

10. A semiconductor light emitting device comprising:
a semiconductor substrate of which material is substantially transparent to a emission wavelength;
a semiconductor multi-layer which emits a light having the emission wavelength by a current injection, a major surface of the semiconductor multi-layer being bonded to a major surface of the semiconductor substrate and the major surface of the semiconductor substrate having a greater area than the major surface of the semiconductor multi-layer;
a first electrode having an ohmic contact part and a light reflecting part, the first electrode being provided on an opposite major surface of the semiconductor multi-layer, a width of the ohmic contact part being wider in an outer part of the first electrode and being narrower in an inner part of the first electrode; and
a second electrode provided on an opposite surface of the semiconductor substrate.

11. The semiconductor light emitting device according to claim 10, wherein a ratio of an area of the ohmic contact part to an area of the first electrode being within a range of 6 to 60%.

12. The semiconductor light emitting device according to claim 10, wherein the ohmic contact part is not provided in a periphery of the first electrode.

13. The semiconductor light emitting device according to claim 10, wherein the ohmic contact part has a concentric or a grid configuration.

14. The semiconductor light emitting device according to claim 10, wherein the semiconductor multi-layer includes a first cladding layer of a first conductivity type, an active layer provided on the first cladding layer, and a second cladding layer of a second conductivity type provided on the active layer.

15. The semiconductor light emitting device according to claim 10, wherein a structure including the semiconductor multi-layer and the first electrode is divided into a plurality of parts.

16. The semiconductor light emitting device according to claim 10, where in a light reflector is disposed on an exposed portion of the major surface of the semiconductor substrate.

17. The semiconductor light emitting device according to claim 10, wherein the semiconductor substrate is made of GaP whose carrier concentration is within a range of 2×10¹⁷ to 3×11¹⁸/cm³.

18. The semiconductor light emitting device according to claim 10, wherein the semiconductor substrate has a trapeziform cross-section having a narrower edge toward the second electrode.

19. A semiconductor light emitting device comprising:
a GaP semiconductor substrate having a first major surface, a second major surface wider than the first major surface and a slanting side surface provided between the first and second major surfaces;
a semiconductor multi-layer including an InGaAlP active layer and a GaAs ohmic contact layer, a major surface of the semiconductor multi-layer being bonded to the second major surface of the GaP substrate and the major surface of the semiconductor multi-layer being smaller than the second major surface of the GaP substrate;
a first electrode having an ohmic contact part and a light reflecting part, the first electrode being provided on the GaAs contact layer; and
a second electrode provided on the first major surface of the GaP substrate.

20. The semiconductor light emitting device according to claim 19, wherein a ratio of an area of the ohmic contact part to an area of the first electrode being within a range of 6 to 60%.
